(19) United States
(12) Patent Application Publication
(10) Pub. No.: US 2016/0268346 A1
(43) Pub. Date: Sep. 15, 2016

(54) A white light OLED display and an encapsulation method thereof

(71) Applicant: SHENZHEN CHINA STAR OPTOELECTRONICS TECHNOLOGY CO., LTD., Shenzhen City, Guangdong (CN)

(72) Inventor: Weijing ZENG, Shenzhen, Guangdong (CN)

(73) Assignee: Shenzhen China Star Optoelectronics Technology Co., Ltd., Shenzhen, Guangdong (CN)

(21) Appl. No.: 14/400,786

(22) PCT Filed: Oct. 11, 2014
(86) PCT No.: PCT/CN2014/088379

§ 371 Date: Nov. 12, 2014

(30) Foreign Application Priority Data
Sep. 30, 2014 (CN) 201410526275.9

(51) Int. Cl. H01L 27/32; H01L 51/52; H01L 51/56

(52) U.S. Cl. CPC H01L 27/322; H01L 51/56; H01L 51/5253; H01L 27/3244; H01L 2227/323

(57) ABSTRACT

The invention provides a white light OLED display, which comprises: a glass cover, a color filter layer coated on the glass cover; a transparent protective layer covering on the color filter layer; a desiccant layer positioned on the transparent protective layer; and a TFT substrate of a white light OLED layer; the color filter layer, the transparent protective layer and the desiccant layer positioned between the glass cover and the TFT substrate of the white light OLED layer. The white light OLED display provided by the invention can protect the color filter layer every well by positioned the transparent protective layer on the color filter layer, and further influence display effect of the white light OLED display.

### FIELD OF THE INVENTION

The invention relates to a technical field of crystal display, particularly related to a white light OLED display and encapsulation method thereof.

### BACKGROUND OF THE INVENTION

OLED is an Organic Light-Emitting Diode with characters of self-illuminating, high-brightness, wide viewing angle, high contrast, flexibility, and low energy consumption, so instead of traditional crystal display, this new generation display getting wide attention is applied widely in mobile screens, computer displays and full color televisions.

Traditional full color displays form RGB three-color pixel on TFT substrates, but because this manufacturing method has high criteria in fine mask, displays with high resolution is hard to achieve. That is why present technologies apply a structure of white light and color filter instead of RGB three-color pixel. A structure of a display with while color and color filter display has related technologies public in patents. At present, common encapsulating technologies are curing glue frame by ultraviolet (UV) light, laser sealing of glass powder, face seal, dam and fill of glue frame and desiccant, film sealing and etc. The encapsulation method of dam and fill is more suitable to apply on an encapsulation of large-size panels. The desiccant dam and fill the whole panel to protect OLED from invasion of hydrogen and oxygen in one way; in the other way, if the TFT substrate and the encapsulation cover can laminate completely to form a stronger mechanical unit, which has better loading-resistance compared to daily loading-resistance of edge encapsulation part. In other words, much-larger units with a certain mechanical loading can be achieved by completely encapsulating portion, but a structure of the encapsulation will cause interference to CF layer, therefore an encapsulating structure is provided to protect the CF layer.

### SUMMARY

The invention provides a white light OLED display and an encapsulation method thereof to solve a technical problem of causing inference to a color filter layer in the present technology.

To solve the aforementioned problem, an embodiment of the invention provides a white light OLED display, and the display comprises: a glass cover; a color filter layer coated on the glass cover; a transparent protective layer covering the color filter layer; a desiccant layer positioned on the transparent protective layer; and a TFT substrate of a OLED layer with white light; the color filter layer, the transparent protective layer and the desiccant layer positioned between the glass cover and the TFT substrate of the OLED layer with white light.

According to a preferred embodiment of the invention, the white light OLED display also comprises a glue frame, which is coated around the color filter layer, the transparent protective layer, and the desiccant layer and the OLED layer with white light, and positioned between the glass cover and the TFT substrate to be used in sealing to protect inner coating layers of the white light OLED display.

According to a preferred embodiment of the invention, the transparent protective layer is tightly Al₂O₃ layer, WO₃ layer, or ZnO layer that cannot occur chemical reaction with the desiccant layer, and an area of the transparent protective layer is equal to or larger than an area of the color filter layer to ensure the transparent protective layer can cover the color filter layer completely.

According to a preferred embodiment of the invention, the glass cover, the color filter layer, the transparent protective layer, the desiccant layer and the TFT substrate of the white light OLED layer are vacuum laminating; the desiccant layer coated via screen printing, drop coating or dispensing; the glue frame is cured around the color filter layer, the transparent protective layer, the desiccant layer and the white light OLED layer by ultraviolet radiation.

According to a preferred embodiment of the invention, the color filter layer is formed by coating RGB photoresistance on the glass cover; the desiccant layer is a curable liquid desiccant and cured on the transparent protective layer by ultraviolet radiation, and the curable liquid desiccant is aluminum polymer with chemical formula of

[R—O—Al═O]n, n≧1.

The embodiment of the invention also provide an encapsulation method of a white light OLED display to solve the aforementioned problem, comprising steps as following: coating a color filter layer on a glass substrate; coating a transparent protective layer on the color filter layer to cover the color filter layer completely; positioning a desiccant layer on the transparent protective layer; forming a white light OLED layer on a TFT substrate; vacuum laminating a encapsulating cover of the TFT substrate with OLED layer, and including the color filter layer, the transparent protective layer and the desiccant layer.

According to a preferred embodiment of the invention, the encapsulation method further comprising a step: sealing to protect inner coating layer of the white light OLED display by coating a glue frame around the color filter layer, the transparent protective layer, the desiccant layer and the white light OLED layer to position the glue frame between the glass cover and the TFT substrate.

According to a preferred embodiment of the invention, the transparent protective layer is tightly Al₂O₃ layer, WO₃ layer, or ZnO layer that cannot occur chemical reaction with the desiccant layer; an area of the transparent protective layer is equal to or larger than an area of the color filter layer to ensure the transparent protective layer can cover the color filter layer completely.

According to a preferred embodiment of the invention, the glass cover, the color filter layer, the transparent protective layer, the desiccant layer and the TFT substrate of the OLED layer with white light OLED layer are vacuum laminating; the desiccant layer is coated via screen printing, drop coating or dispensing; the glue frame is cured around the color filter layer, the transparent protective layer, the desiccant layer and the white light OLED layer by ultraviolet radiation.

According to a preferred embodiment of the invention, the color filter layer is formed by coating RGB photoresistance on the glass cover; the desiccant layer is a curable liquid desiccant and cured on the transparent protective layer by ultraviolet radiation, and the curable liquid desiccant is aluminum polymer with chemical formula of [R—O—Al═O]n, n≧1.

Compared to the present technologies, the white light OLED display and the encapsulation method provided by the invention can protect the color filter layer every well by positioned the transparent protective layer on the color filter layer, and further influence display effect of the white light OLED display.

### BRIEF DESCRIPTION OF THE DRAWING

Reference will now be made in detail to example embodiments, examples of which are illustrated in the accompanying drawings, the present example embodiments may have different forms and should not be construed as being limited to the descriptions set forth herein. Specific structural and functional details disclosed herein are merely representative for purposes of describing example embodiments, and thus may be embodied in many alternate forms and should not be construed as limited to only example embodiments set forth herein. Therefore, it should be understood that there is no intent to limit example embodiments to the particular forms disclosed, but on the contrary, example embodiments are to cover all modifications, equivalents, and alternatives falling within the scope of the disclosure.

FIG. 1 is a structural schematic view of a white light OLED display of the invention.

FIG. 2 is an encapsulating flowchart of encapsulation method of a white light OLED display of the invention.

### DETAILED DESCRIPTION OF THE EMBODIMENTS

In order to make the present invention more understandable and complete, references are made to detailed descriptions set forth hereinafter in conjunction with the preferred embodiment of the invention and figures. Obviously, the descriptive embodiments are only part of embodiments of the invention, but not all of the embodiments. Based on the embodiment of the invention, other embodiments obtained by a person killed in the art without inventive diligent belong to the invention claims.

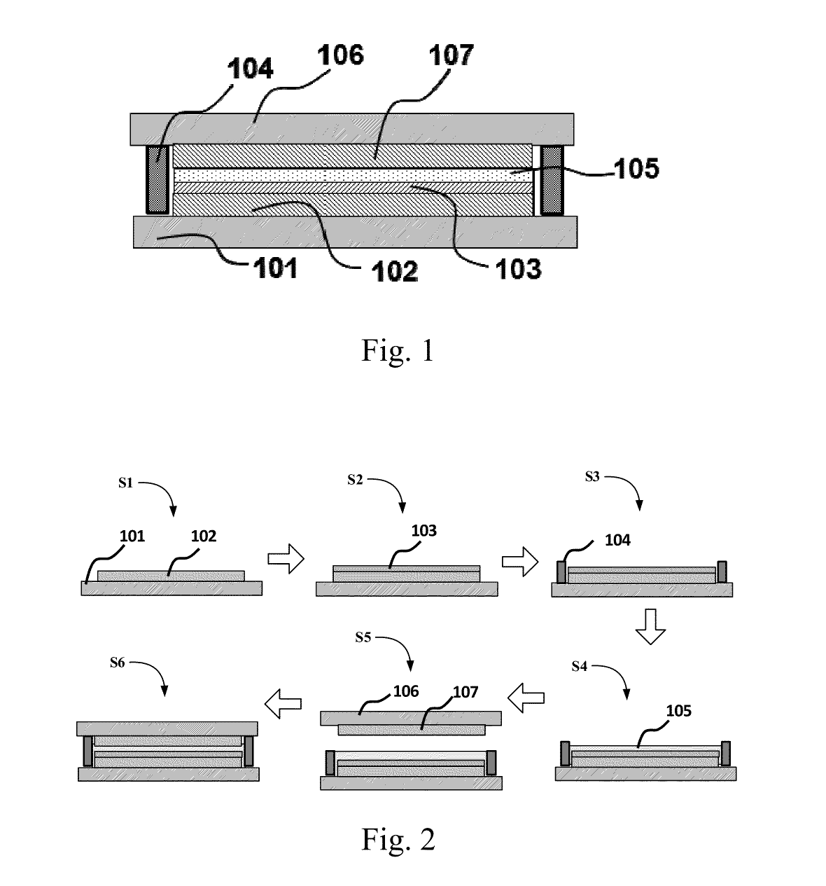

Please refer to FIG. 1. FIG. 1 shows a structural schematic view of a preferred embodiment of a white light OLED display of the invention, and the white light OLED display comprises: a glass cover 101, a color filter (CF) layer 102, a transparent protective layer 103, a desiccant layer 105, a white light OLED layer 107 and a TFT (Thin Film Transistor) substrate 106.

Concretely, a color filter layer 102 is coated on the glass cover 101; the color filter layer 102 is formed by coating RGB photoresistance on the glass cover 101.

The transparent protective layer 103 is covering the color filter layer 102; wherein, the transparent protective layer 103 is tightly Al₂O₃ layer, WO₃ layer, or ZnO layer that cannot occur chemical reaction with the desiccant layer 105; the transparent protective layer 103 can surely be a coating layer of other inorganic materials, which is not be limited here.

Moreover, an area of the transparent protective layer 103 is equal to or larger than an area of the color filter layer 102 to ensure the transparent protective layer 103 can cover the color filter layer 102 completely, and to protect the color filter layer 102 entirely.

A desiccant layer 105 is positioned on the transparent protective layer 103; the desiccant layer 105 is coated via screen printing, drop coating or dispensing and etc.; the desiccant layer 105 is a curable liquid desiccant, ex: thermosetting liquid desiccant, and cured on the transparent protective layer 103 by ultraviolet radiation, wherein, the curable liquid desiccant is aluminum polymer with chemical formula of

[R—O—Al═O]n, n≧1.

The white light OLED layer 107 is positioned on the TFT substrate 106; wherein, the glass cover 101, the color filter layer 102, the transparent protective layer 103, the desiccant layer 105 and the TFT substrate 106 with the white light OLED layer 107 are vacuum laminating to ensure all substrate layers will not influence a display effect of a crystal display because of existing bobbles.

Preferably, the white light OLED display further comprises a glue frame 104, which is coated around the color filter layer 102, the transparent protective layer 103, the desiccant layer 105 and the white light OLED layer 107, and that is outside AA (Active Area) of the glass cover 101; the glue frame 104 is further positioned between the glass cover 101 and the TFT substrate 106 to be used in sealing to protect inner coating layers of the white light OLED display; the glue frame 104 is cured around the color filter layer 102, the transparent protective layer 103, the desiccant layer 105 and the white light OLED layer 107 by ultraviolet radiation.

By positioning a transparent protective layer on a color filter layer, the white light OLED display provided by the embodiment of the invention can reach a very well protective function, avoid producing interference to the color filter layer during a encapsulating procedure, and further influence a display effect of the white light OLED display.

The invention also provides an encapsulation method of a white light OLED display, and please refer to FIG. 2, which shows a encapsulating flowchart of encapsulation method of the white light OLED display of the invention, and the encapsulation method comprises but not limited to the following steps:

STEP 1: coating RGB photoresistance on the glass cover 101 to form CF (color filter) layer 102, which is covering an AA (Active Area) area of a display.

STEP 2: forming a transparent protective layer 103 on the color filter layer 102, and an area of the transparent protective layer is equal to or larger than an area of the color filter layer to ensure the transparent protective layer can cover the color filter layer completely to protect the color filter layer entirely.

The transparent protective layer 103 is tightly Al₂O₃ layer, WO₃ layer, or ZnO layer that cannot occur chemical reaction with the desiccant layer 105; the transparent protective layer 103 can surely be a coating layer of other inorganic materials, which is not be limited herein.

STEP 3: coating a glue frame 104 outside an AA (Active Area) of the glass cover 101.

STEP 4: coating a liquid desiccant 105 inside an area of the glue frame 104; the desiccant layer is coated via screen printing, drop coating or dispensing and etc.; the desiccant layer 105 is a curable liquid desiccant, ex. thermosetting liquid desiccant, and cured on the transparent protective layer 103 by ultraviolet radiation, wherein, the curable liquid desiccant is aluminum polymer with chemical formula of

[R—O—Al═O]n, n≧1.

The glue frame 104 is coated around the color filter layer 102, the transparent protective layer 103, the desiccant layer 105 and the white light OLED layer 107, and that is outside AA (Active Area) of the glass cover 101; the glue frame 104 is further positioned between the glass cover 101 and the TFT substrate 106 with white light OLED layer 107 and used in sealing to protect inner coating layers of the white light OLED display.

STEP 5: vacuum laminating the glass cover 101, the color filter layer 102, the transparent protective layer 103 and the desiccant layer 105 and the TFT substrate 106 of the white light OLED layer 107.

STEP 6: UV curing the glue frame 104. The glue frame 104 is cured around the color filter layer 102, the transparent protective layer 103, the desiccant layer 105 and the white light OLED layer 107 by ultraviolet radiation or other heating sources.

The encapsulation method of the white light OLED display provided by the embodiment of the invention can reach a very well protective function, avoid producing interference to the color filter layer during a encapsulating procedure, further influence a display effect of the white light OLED display; moreover, to ensure reliable firming and well sealing of every substrates of a display by curing the glue frame via ultraviolet light.

The aforementioned is only one embodiment of the invention, but not for limiting the claims of the invention; any equivalent device or equivalent effect flowchart, or directly or indirectly application in other related technical fields are all included in the claims of the invention.

1. A white light OLED display, characterized in that the display comprises:
a glass cover;
a color filter layer coated on the glass cover;
a transparent protective layer covering the color filter layer;
a desiccant layer positioned on the transparent protective layer;
a TFT substrate of a white light OLED layer;
a glue frame coated around the color filter layer, the transparent protective layer, and the white light OLED layer, and positioned between the glass cover and the TFT substrate, and used in sealing to protect inner coating layers of the white light OLED display;
the color filter layer, the transparent protective layer and the desiccant layer positioned between the glass cover and the TFT substrate of the white light OLED layer;
the glass cover, the color filter layer, the transparent protective layer and the desiccant layer vacuum laminating with the TFT substrate of the white light OLED layer, the desiccant layer coated via screen printing, drop coating or dispensing, and the glue frame cured around the color filter layer, the transparent protective layer, the desiccant layer and the white light OLED layer by ultraviolet radiation.

2. A white light OLED display, characterized in that the display comprises:
a glass cover;
a color filter layer coated on the glass cover;
a transparent protective layer covering on the color filter layer;
a desiccant layer positioned on the transparent protective layer;
a TFT substrate of a white light OLED layer;
the color filter layer, the transparent protective layer and the desiccant layer positioned between the glass cover and the TFT substrate of the white light OLED layer.

3. The white light OLED display according to claim 2, characterized in that the white light OLED display further comprises a glue frame, which is coated around the color filter layer, the transparent protective layer, the desiccant layer and the white light OLED layer, and positioned between the glass cover and the TFT substrate to be used in sealing to protect inner coating layers of the white light OLED display.

4. The white light OLED display according to claim 3, characterized in that the transparent protective layer is tightly Al₂O₃ layer, WO₃ layer, or ZnO layer that cannot occur chemical reaction with the desiccant layer.

5. The white light OLED display according to claim 4, characterized in that an area of the transparent protective layer is equal to or larger than an area of the color filter layer to ensure the transparent protective layer can cover the color filter layer completely.

6. The white light OLED display according to claim 2, characterized in that the glass cover, the color filter layer, the transparent protective layer, the desiccant layer and the TFT substrate with the white light OLED layer are vacuum laminating.

7. The white light OLED display according to claim 6, characterized in that the desiccant layer is coated via screen printing, drop coating or dispensing.

8. The white light OLED display according to claim 7, characterized in that the glue frame is cured around the color filter layer, the transparent protective layer, the desiccant layer and the white light OLED layer by ultraviolet radiation.

9. The white light OLED display according to claim 8, characterized in that the color filter layer is formed by coating RGB photoresistance on the glass cover.

10. The white light OLED display according to claim 9, characterized in that the desiccant layer is a curable liquid desiccant and cured on the transparent protective layer by ultraviolet radiation, and the curable liquid desiccant is aluminum polymer with chemical formula of
[R—O—Al═O]n, n≧1.

11. An encapsulation method of a white light OLED display, characterized in that comprising following steps:
coating a color filter layer on a glass substrate;
coating a transparent protective layer on the color filter layer to cover the color filter layer completely;
positioning a desiccant layer on the transparent protective layer;
forming a white light OLED layer on a TFT substrate;
laminating a encapsulating cover of the TFT substrate with OLED layer, and including the color filter layer, the transparent protective layer and the desiccant layer in vacuum environment.

12. The encapsulation method according to claim 11, characterized in that the encapsulation method further comprising a step: sealing to protect inner coating layer of the white light OLED display by coating a glue frame around the color filter layer, the transparent protective layer, the desiccant layer and the white light OLED layer to position the glue frame between the glass cover and the TFT substrate.

13. The encapsulation method according to claim 12, characterized in that the transparent protective layer is tightly Al₂O₃ layer, WO₃ layer, or ZnO layer that cannot occur chemical reaction with the desiccant layer.

14. The encapsulation method according to claim 13, characterized in that an area of the transparent protective layer is equal to or larger than an area of the color filter layer to ensure the transparent protective layer can cover the color filter layer completely.

15. The encapsulation method according to claim 11, characterized in that the glass cover, the color filter layer, the transparent protective layer, the desiccant layer and the TFT substrate of the white light OLED layer are vacuum laminating.

16. The encapsulation method according to claim 15, characterized in that the desiccant layer coated via screen printing, drop coating or dispensing.

17. The encapsulation method according to claim 16, characterized in that the glue frame is cured around the color filter layer, the transparent protective layer, the desiccant layer and the white light OLED layer by ultraviolet radiation.

18. The encapsulation method according to claim 17, characterized in that the color filter layer is formed by coating RGB photoresistance on the glass cover.

19. The encapsulation method according to claim 18, characterized in that the desiccant layer is a curable liquid desiccant and cured on the transparent protective layer by ultraviolet radiation, and the curable liquid desiccant is aluminum polymer with chemical formula of
[R—O—Al═O]n, n≧1.
